(19) United States
(12) Patent Application Publication
(10) Pub. No.: US 2011/0062599 A1
(43) Pub. Date: Mar. 17, 2011

(54) INTEGRATED CIRCUIT PACKAGING SYSTEM WITH PACKAGE STACKING AND METHOD OF MANUFACTURE THEREOF

(76) Inventors: Joon Dong Kim, Dongdaemun-gu (KR); Seong Won Park, Icheon-si (KR); Byoung Wook Jang, Yong-in (KR)

(21) Appl. No.: 12/561,929

(22) Filed: Sep. 17, 2009

(51) Int. Cl. H01L 21/60; H01L 23/48

(52) U.S. Cl. 257/778; 438/108; 257/E21.511; 257/E23.01

(57) ABSTRACT

A method of manufacture of an integrated circuit packaging system includes: providing a base package substrate; mounting a flip chip integrated circuit die on the base package substrate; applying a flip chip protective layer on the flip chip integrated circuit die including covering only a back side of the flip chip integrated circuit die; and mounting an upper package on the base package substrate including positioning an upper package substrate adjacent to the flip chip protective layer.

### TECHNICAL FIELD

The present invention relates generally to an integrated circuit packaging system, and more particularly to a system for producing a package-on-package stacking system.

### BACKGROUND ART

Important and constant goals of the computer industry include higher performance, lower cost, increased miniaturization of components, and greater packaging density for integrated circuits (“ICs”). As new generations of IC products are released, the number of IC devices needed to fabricate them tends to decrease due to advances in technology. Simultaneously, the functionality of these IC products increases. For example, on the average there is approximately a 10 percent decrease in components required for every IC product generation over a previous generation having equivalent functionality.

Semiconductor package structures continue to become thinner and ever more miniaturized. This results in increased component density in semiconductor packages and decreased sizes of the IC products in which the packages are used. These developmental trends are in response to continually increasing demands on electronic apparatus designers and manufacturers for ever-reduced sizes, thicknesses, and costs, along with continuously improving performance.

These increasing requirements for miniaturization are particularly noteworthy, for example, in portable information and communication devices such as cell phones, hands-free cell phone headsets, personal data assistants (“PDA's”), camcorders, notebook personal computers, and so forth. All of these devices continue to be made smaller and thinner to improve their portability. Accordingly, large-scale integration (“LSI”) packages incorporated into these devices, as well as the package configurations that house and protect them, must also be made smaller and thinner.

Many conventional semiconductor chip or die packages are of the type having a semiconductor die molded into a package with a resin, such as an epoxy molding compound. The packages have a leadframe whose out leads are projected from the package body to provide a path for signal transfer between the chip and external devices. Other conventional package configurations have contact terminals or pads formed directly on the surface of the package.

In IC packaging, in addition to component size reduction, surface mount technology (“SMT”) has demonstrated an increase in semiconductor chip density on a single substrate (such as a printed circuit board (“PCB”)) despite the reduction in the number of components. SMT is a method used to connect packaged chips to substrates. With SMT, no through-holes in the substrate are required. Instead, package leads are soldered directly to the substrate surface. This results in more compact designs and form factors, and a significant increase in IC density and performance. However, despite these several reductions in size, IC density continues to be limited by the space or “real estate” available for mounting chips on a substrate.

One method to further increase IC density is to stack semiconductor chips vertically. Multiple stacked chips can be combined into a single package in this manner with a very small surface area or “footprint” on the PCB or other substrate. This strategy of stacking IC components vertically has in fact been extended to the stacking of entire packages upon each other. Such package-on-package (“PoP”) configurations continue to become increasingly popular as the semiconductor industry continues to demand semiconductor devices with lower costs, higher performance, increased miniaturization, and greater packaging densities. Continuing substantial improvements in PoP technology are anticipated to address these requirements.

Unfortunately, limitations of current PoP stacking techniques can interfere with the ready incorporation and utilization of existing die and package configurations. It can reduce the effective reliability of the package due to movement of the packages with changes in temperature. The movement or warping of package substrates can damage die exposed on a base substrate or fracture interconnects between the substrates.

For example, in a previous PoP configuration, the base package has bonding pads on the top side that allow surface mounting of a top or second package. In order to successfully and effectively mount the top package on the base package, it is necessary to have sufficient clearance or “headroom” between the packages for accommodating structures, such as dies or a mold cap, on the top of the base package. However, typically due to cost and efficiency considerations, the only physical structure connecting the top package and the base package is the electrical interface between them. This electrical interface is usually a solder ball matrix on the bottom of the top package that aligns with bonding pads on the top of the base package.

Previous techniques employing such solder ball matrices usually afford only a small space or stand-off provided by the nominal height of the solder balls. This limits the available height for the base package components on the top of the base package, such as one or more semiconductor dice. Since the primary goal of the integration is to reduce the size of the package clearances are held to a minimum.

The problem of limited space between the base package and the top package increases the critical dimensions and manufacturing difficulty of the PoP. The integrated circuit die on the base package, if exposed, may be damaged during or after assembly by the movement of the two packages caused by different rates of thermal expansion and rigidity.

Thus, while a need still remains for smaller, thinner, lighter, less-expensive integrated circuit PoP systems, a great need also remains for PoP systems that simplify the assembly process and help address the warping issue that can damage the integrated circuit die of the base package. In view of the ever-increasing commercial competitive pressures, along with growing consumer expectations and the diminishing opportunities for meaningful product differentiation in the marketplace, it is critical that answers be found for these problems. Additionally, the need to save costs, improve efficiencies and performance, and meet competitive pressures, adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit packaging system including: providing a base package substrate; mounting a flip chip integrated circuit die on the base package substrate; applying a flip chip protective layer on the flip chip integrated circuit die including covering only a back side of the flip chip integrated circuit die; and mounting an upper package on the base package substrate including positioning an upper package substrate adjacent to the flip chip protective layer.

The present invention provides an integrated circuit packaging system including: a base package substrate; a flip chip integrated circuit die on the base package substrate; a flip chip protective layer on the flip chip integrated circuit die including covering only a back side of the flip chip integrated circuit die; and an upper package on the base package substrate including an upper package substrate adjacent to the flip chip protective layer.

Certain embodiments of the invention have other steps or elements in addition to or in place of those mentioned above. The steps or element will become apparent to those skilled in the art from a reading of the following detailed description when taken with reference to the accompanying drawings.

### BRIEF DESCRIPTION OF THE DRAWINGS

FIG. 1 is a top view of an integrated circuit packaging system in an embodiment of the present invention.

FIG. 2 is a cross-sectional view of an integrated circuit packaging system as viewed along the section line 2-2, of FIG. 1.

FIG. 3 is a cross-sectional view of an integrated circuit packaging system with package stacking in an embodiment of the present invention.

FIG. 4 is a top view of a manufacturing tray having the integrated circuit packaging system positioned therein.

FIG. 5 is a cross-sectional view of a pick and place device as used in manufacturing the integrated circuit packaging system.

FIG. 6 is a flow chart of a manufacturing process for producing the base package.

FIG. 7 is an exploded cross-section of the base package.

FIG. 8A is a characterization of an upper package having a bend or warp at 25 degrees Celsius.

FIG. 8B is a characterization of a base package having a bend or warp at 25 degrees Celsius.

FIG. 8C is a characterization of an upper package having a bend or warp at 260 degrees Celsius.

FIG. 8D is a characterization of a base package having a bend or warp at 260 degrees Celsius.

FIG. 9 is a flow chart of a method of manufacture of an integrated circuit packaging system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings for ease of description generally show similar orientations, this depiction in the FIGs. is arbitrary for the most part. Generally, the invention can be operated in any orientation.

Where multiple embodiments are disclosed and described, having some features in common, for clarity and ease of illustration, description, and comprehension thereof, similar and like features one to another will ordinarily be described with similar reference numerals.

For expository purposes, the term “horizontal” as used herein is defined as a plane parallel to the plane or surface of the integrated circuit die, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures. The term “on” means that there is direct contact among elements.

The term “processing” as used herein includes deposition of material or photoresist, patterning, exposure, development, etching, cleaning, and/or removal of the material or photoresist as required in forming a described structure.

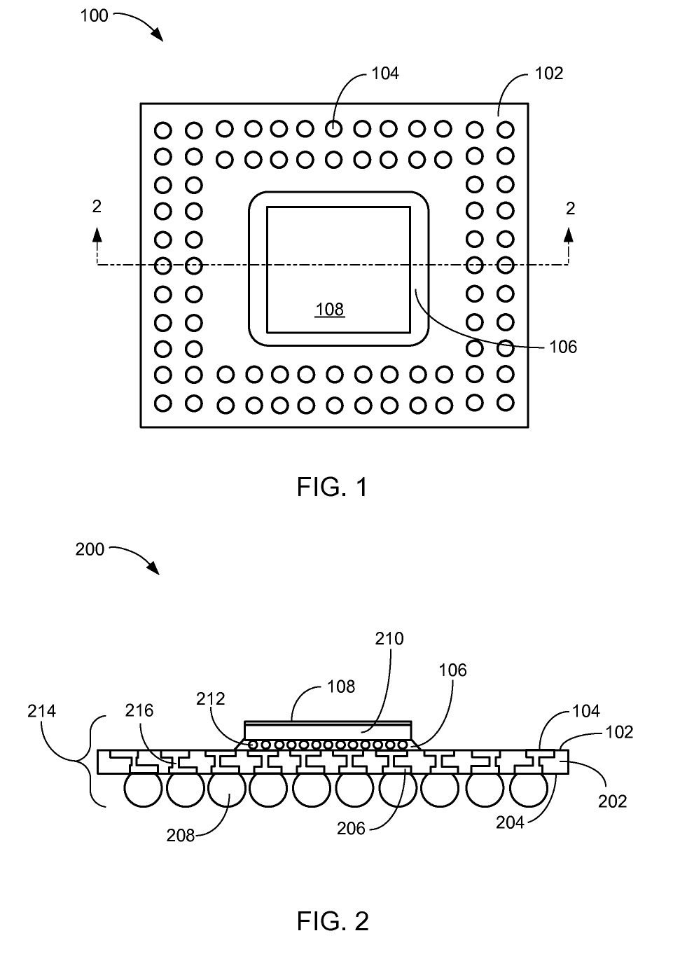

Referring now to FIG. 1, therein is shown a top view of an integrated circuit packaging system 100 in an embodiment of the present invention. The top view of the integrated circuit packaging system 100 depicts a base package component side 102 having an array of bonding pads 104 arranges thereon.

It is understood that the number and position of the bonding pads 104 is an example only and the actual number and position of the bonding pads 104 may differ. It is further understood that the structure of FIG. 1 is shown without solder mask, but solder mask may be present in the actual implementation of the integrated circuit packaging system 100.

An under fill material 106 may protect the connections of an integrated circuit die (not shown) that may be coupled to the base package component side 102. A flip chip protective layer 108, such as a ceramic or polymer, may completely cover the backside of the integrated circuit die.

The flip chip protective layer 108 may be applied by a film coating, a spray-on coating, a liquid coating, or a combination thereof. The flip chip protective layer 108 may provide a structural reinforcement and insulation from pressure by disbursing the pressure across the surface.

A section line 2-2 indicates the position and viewing direction of the cross-sectional view of FIG. 2.

Referring now to FIG. 2, therein is shown a cross-sectional view of an integrated circuit packaging system 200 as viewed along the section line 2-2, of FIG. 1. The cross-sectional view of the integrated circuit packaging system 200 depicts a base package substrate 202 having a system side 204 with system contact pads 206. System interconnects 208, such as solder balls, solder columns, solder bumps, or stud bumps, may be formed on the system contact pads 206.

A flip chip integrated circuit die 210 may be coupled to the bonding pads 104 by chip interconnects 212, such as solder balls. The under fill material 106 may be applied between the flip chip integrated circuit die 210 and the base package component side 102 to engulf the chip interconnects 212.

The flip chip protective layer 108 may be applied to the backside of the flip chip integrated circuit die 210 during the assembly process of a base package 214. The flip chip protective layer 108 may completely cover the backside of the flip chip integrated circuit die 210 and may contact the vertical sides but remains spaced away from to the under fill material 106.

It has been discovered that the application of the flip chip protective layer 108 on the flip chip integrated circuit die 210 may prevent damage to the flip chip integrated circuit die 210 during the assembly process and operation of the base package 214. The base package 214 has no molded support structure or epoxy molding compound on the flip chip integrated circuit die 210.

An inner layer via 216 may form a connection between the bonding pads 104 and the system contact pads 206. The mounting of the flip chip integrated circuit die 210 to the bonding pads 104, through the chip interconnects 212, may provide an electrical connection to other instances of the bonding pads 104, the system interconnects 208, or a combination thereof.

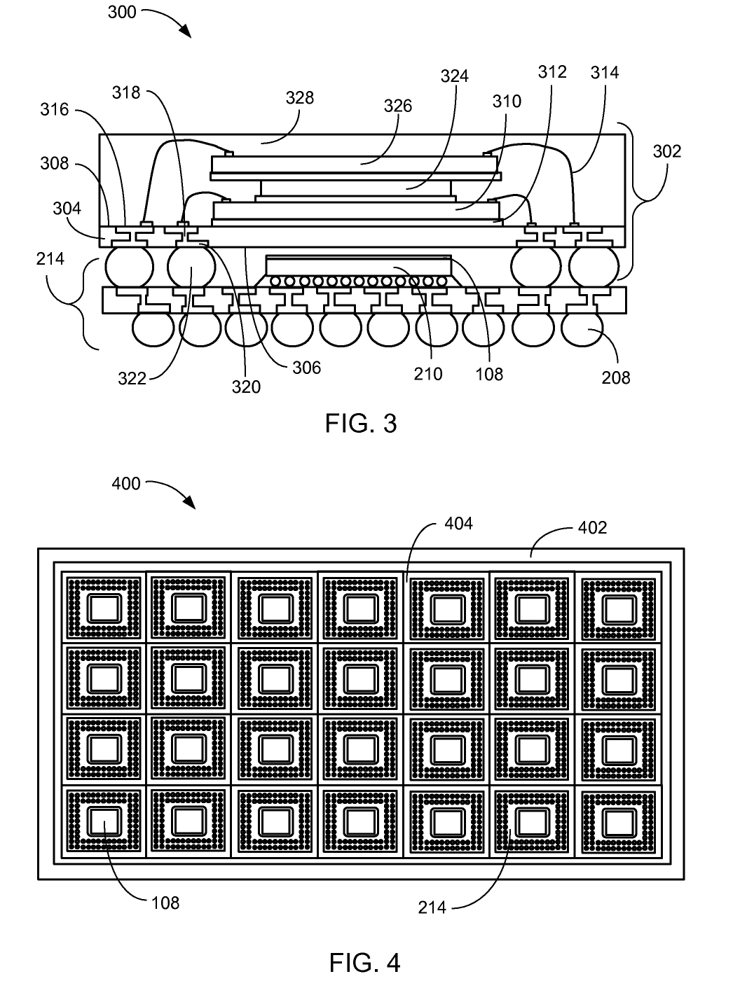

Referring now to FIG. 3, therein is shown a cross-sectional view of an integrated circuit packaging system 300 with package stacking in an embodiment of the present invention. The cross-sectional view of the integrated circuit packaging system 300 depicts the base package 214 having the flip chip integrated circuit die 210 mounted thereon. The flip chip protective layer 108 may be applied to the backside of the flip chip integrated circuit die 210.

An upper package 302 may include an upper package substrate 304, having a bottom side 306 facing the base package 214 and a top side 308. A first integrated circuit die 310, such as a wire bond type chip, may be mounted on the top side 308 by an adhesive 312.

Electrical interconnects 314, such as bond wires, may electrically connect the first integrated circuit die 310 to the base package 214 through top side contacts 316, upper package vias 318, bottom side contacts 320, and stacked interconnects 322, such as solder columns, stud bumps, or solder balls of a controlled size. A chip spacer 324 may be mounted over the first integrated circuit die 310 as a mounting platform for a second integrated circuit die 326, such as a wire bond type chip.

The electrical interconnects 314 may couple the second integrated circuit die 326 to the top side contacts 316. This coupling may provide an electrical connection from the second integrated circuit die 326 to the first integrated circuit die 310, the flip chip integrated circuit die 210, the system interconnects 208, or a combination thereof. An upper package body 328, such as epoxy molding compound, may be formed on the top side 308 of the upper package substrate 304, the first integrated circuit die 310, the adhesive 312, the electrical interconnects 314, the chip spacer 324, and the second integrated circuit die 326.

It is understood that the first integrated circuit die 310 and the second integrated circuit die 326 of the upper package 302 are examples only. Any number or type of chips may be present in the upper package 302. The goal of such a design is to increase the functional density while reducing the space required for the functions. With that goal in mind, the minimum spacing is maintained between the bottom side 306, of the upper package substrate 304, adjacent to the flip chip protective layer 108 on the flip chip integrated circuit die 210.

The resulting stacked package structure is a package-on-package device. It is known that during the operation of package-on-package devices a warping of the base package substrate 202 and the upper package substrate 304 may occur. In the event that the warping causes the bottom side 306, of the upper package substrate 304, to physically contact the flip chip protective layer 108 no damage will occur to the flip chip integrated circuit die 210.

It has been discovered that the presence of the flip chip protective layer 108 distributes the pressure from the physical contact without causing damage to the flip chip integrated circuit die 210. This becomes extremely critical when the flip chip integrated circuit die 210 is an ultra-thin chip, as is desirable in the package-on-package structure.

It is also noted that due to the characteristic collapse of the stacked interconnects 322 during reflow, providing a known clearance between the bottom side 306, of the upper package substrate 304, and the flip chip protective layer 108 is virtually impossible and initial physical contact is likely. The presence of the flip chip protective layer 108 may provide an increase in manufacturing yield and operational reliability by sheltering the flip chip integrated circuit die 210 from the physical contact.

Referring now to FIG. 4, therein is shown a top view of a manufacturing tray 400 having the integrated circuit packaging system 100 positioned therein. The top view of the manufacturing tray 400 depicts an anti-static tray 402 having an array of seated locations 404 for receiving the base package 214.

During the manufacturing process, the array of the seated locations 404 may contain the base package 214 in order to protect them during transport and handling. The base package 214 may be removed and replaced in the anti-static tray 402 repeatedly for inspection, marking, and test.

The presence of the flip chip protective layer 108 may provide additional robustness of the flip chip integrated circuit die 210, of FIG. 2. to prevent possible fracture of the device during handling. It has been discovered that the application of the flip chip protective layer 108 may provide the additional robustness required mounting an ultra-thinned version of the flip chip integrated circuit die 210.

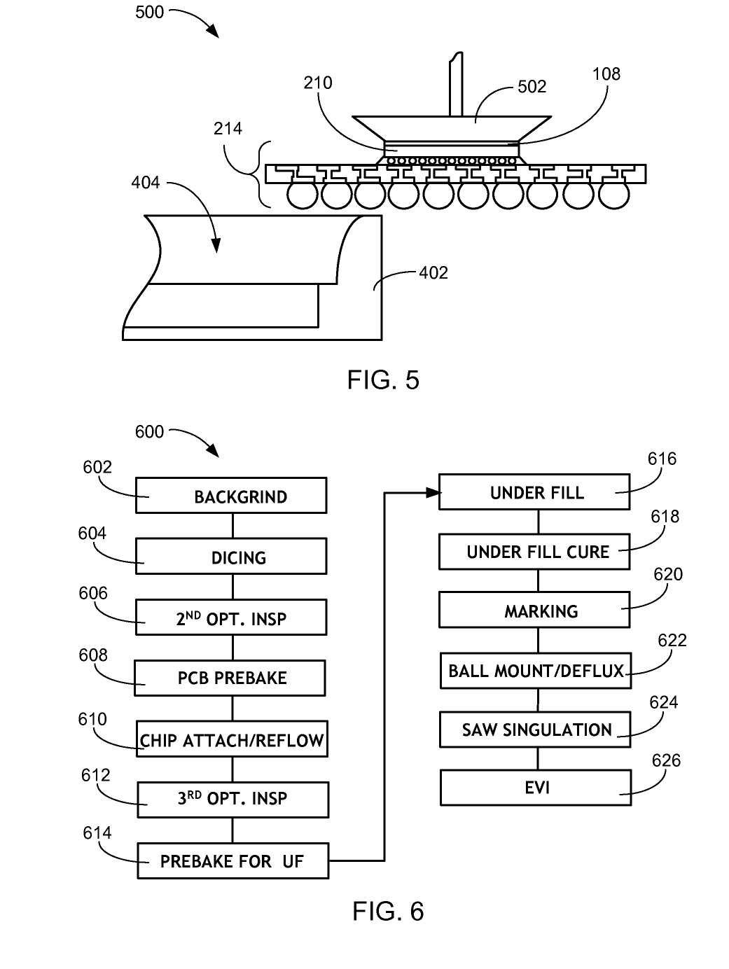

Referring now to FIG. 5, therein is shown a cross-sectional view of a pick and place device 500 as used in manufacturing the integrated circuit packaging system 100. The cross-sectional view of the pick and place device 500 depicts a pick-and-place chuck 502, such as a vacuum head, for selecting and lifting individual units of the base package 214 out of the seated location 404 of the anti-static tray 402.

The pick-and-place chuck 502 may apply a vacuum to the surface of the flip chip protective layer 108 in order to lift the base package 214 out of the seated location 404. The vacuum pressure may be sufficient to fracture the flip chip integrated circuit die 210 if the flip chip protective layer 108 was not present. The addition of the flip chip protective layer 108 may improve the manufacturing yield by preventing micro fractures of the flip chip integrated circuit die 210 during handling.

Referring now to FIG. 6, therein is shown a flow chart of a manufacturing process 600 for producing the base package 214. The flow chart of the manufacturing process 600 depicts a backgrinding 602. In this process step a wafer containing the flip chip integrated circuit die 210, of FIG. 2, may be thinned in preparation for singulating the flip chip integrated circuit die 210 from the wafer.

A dicing step 604 may separate the individual units of the flip chip integrated circuit die 210. The singulated units of the flip chip integrated circuit die 210 may progress to a 2^{nd} Optical Inspection station 606 where the dice are checked for cracks or breakage.

A PCB Pre-bake station 608 may elevate the temperature of the singulated dice and a printed circuit board panel containing an array of the base package substrate 202, of FIG. 2, in preparation for assembly. A chip attach and reflow station 610 provides the solder paste and positioning of the flip chip integrated circuit die 210, in order to form the chip interconnects 212, of FIG. 2. In this process step, the flip chip protective layer 108 may also be applied.

A third optical inspection station 612 may verify that the flip chip integrated circuit die 210 are properly attached to the base package substrate 202 and that the flip chip protective layer 108 is in place. The inspected devices may be transported to a Pre-bake for under fill station 614. An under fill station 616 may apply the under fill material 106, of FIG. 1, while the assembly is at temperature.

An under fill curing station 618 may subject the under fill material 106 to an ultra-violet light or other curing mechanism to harden the under fill material 106. The assemblies may be transported to a marking station 620. In the marking station 620, information such as the manufacturing date code, manufacturing location, wafer source numbers, and the like may be applied to the assembly.

A ball mount/deflux station 622 may form the system interconnects 208, of FIG. 2, and remove the residue of the organic solder preparation (OSP) known as flux. In a saw singulation step 624, the printed circuit board panel containing the array of the base package substrate 202 is cut apart and the individual components are placed in the anti-static tray 402, of FIG. 4.

In a final step, the base package 214, of FIG. 2, are tested in an Electronic Verification and Inspection (EVI) station 626. The base package 214 is now ready for assembling the integrated circuit packaging system 300, as a package-on-package device.

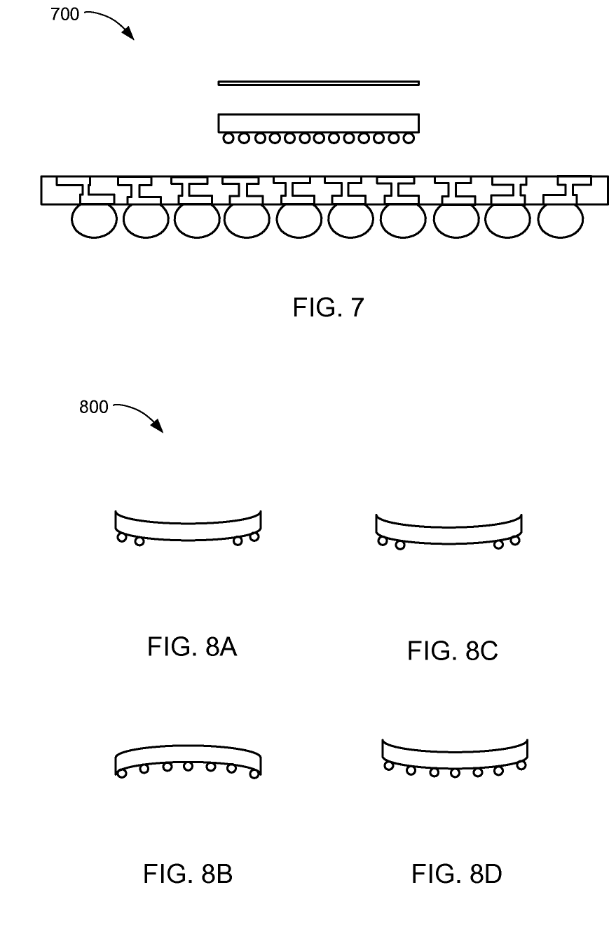

Referring now to FIG. 7, therein is shown an exploded cross-section of the base package 214. The exploded cross-section of the base package 214 depicts the base package substrate 202 having the system interconnects 208 attached thereon.

The flip chip integrated circuit die 210, having the chip interconnects 212 formed on the active side thereof. The flip chip protective layer 108 may be applied to the back side of the flip chip integrated circuit die 210.

It has been discovered that by applying the flip chip protective layer 108 to the flip chip integrated circuit die 210, the manufacturing yield may increase and the operational reliability of the flip chip integrated circuit die 210 is improved. The manufacturing process associated the assembly of the base package 214 may subject the base package substrate 202 to stress from thermal cycling associated with PCB storage, PCB preparation, die attach, under fill, and back to storage.

The temperatures associated with these processes may vary between 25 degrees Celsius and 260 degrees Celsius. This wide range of temperatures may impose a warping bias on the base package substrate. The warping may become obvious as the base package 214 is cooled back to ambient temperature. The presence of the flip chip protective layer 108 may prevent the stress provided by the warping under temperature variation from damaging the flip chip integrated circuit die 210.

Referring now to FIG. 8A, therein is shown a characterization of an upper package 802 having a bend or warp at 25 degrees Celsius. The characterization of the upper package 802 depicts the substrate of the upper package 802 having the outside edges deflected upwards relative to the center region.

This deflection may be caused by varying densities of metal in the regions of the substrate or a high density of contact pads on the upper surface as compared to a lower number of the contact pads on the bottom surface. The stresses associated with the thermal cycling may induce the effect known as “potato chip”.

Referring now to FIG. 8B, therein is shown a characterization of a base package 804 having a bend or warp at 25 degrees Celsius. The characterization of the base package 804 depicts the substrate of the base package 804 having the outside edges deflected downward relative to the center region.

Once again the deflection may be caused by the varying densities of metal in the regions of the substrate or a high density of contact pads on the center of the upper surface as compared to a broadly dispersed number of the contact pads on the bottom surface. This reverse “potato chip” may cause difficult clearance issues when an assembled package-on-package device is cooled back to room temperature.

Referring now to FIG. 8C, therein is shown a characterization of an upper package 802 having a bend or warp at 260 degrees Celsius. The characterization of an upper package 802 depicts a similar deflection of the outside edges as what was seen at the ambient temperature of 25 degrees Celsius.

Referring now to FIG. 8D, therein is shown a characterization of a base package 804 having a bend or warp at 260 degrees Celsius. The characterization of a base package 804 depicts the outside edges deflected upwards relative to the center region.

This deflection may be caused by varying densities of metal in the regions of the substrate or a high density of contact pads on the center of the upper surface as compared to a lower density of the contact pads on the bottom surface. The stresses associated with the thermal cycling may induce the effect known as “potato chip” but in a reverse direction.

During the assembly process the temperature may cycle from an ambient of 25 degrees Celsius to a peak in the range of 300 degrees Celsius. Maintaining any critical clearance measurements may be extremely difficult given the possibility of the base package 804 changing the direction of deflection across the temperature range.

Thus, it has been discovered that the integrated circuit packaging system and device of the present invention furnishes important and heretofore unknown and unavailable solutions, capabilities, and functional aspects for manufacturing package-on-package devices with improved manufacturing yield and reliability.

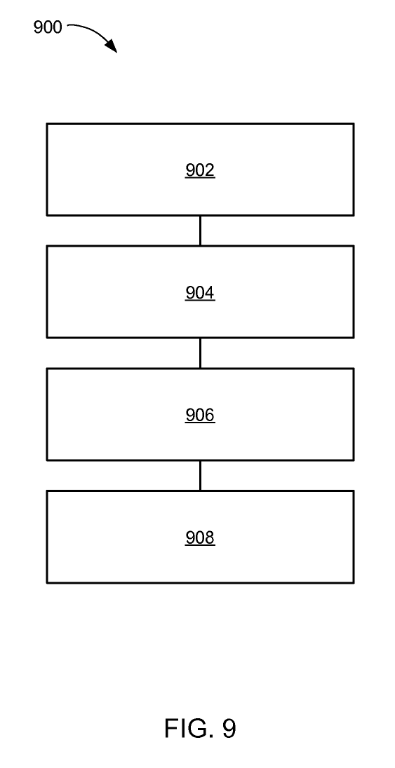

Referring now to FIG. 9, therein is shown a flow chart of a method 900 of manufacture of the integrated circuit packaging system 100 in an embodiment of the present invention. The method 900 includes: providing a base package substrate in a block 902; mounting a flip chip integrated circuit die on the base package substrate in a block 904; applying a flip chip protective layer on the flip chip integrated circuit die including covering only a back side of the flip chip integrated circuit die in a block 906; and mounting an upper package on the base package substrate including positioning an upper package substrate adjacent to the flip chip protective layer in a block 908.

The resulting method, process, apparatus, device, product, and/or system is straightforward, cost-effective, uncomplicated, highly versatile and effective, can be surprisingly and unobviously implemented by adapting known technologies, and are thus readily suited for efficiently and economically manufacturing package-on-package systems fully compatible with conventional manufacturing methods or processes and technologies.

Another important aspect of the present invention is that it valuably supports and services the historical trend of reducing costs, simplifying systems, and increasing performance.

These and other valuable aspects of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit packaging system comprising:
providing a base package substrate;
mounting a flip chip integrated circuit die on the base package substrate;
applying a flip chip protective layer on the flip chip integrated circuit die including covering only a back side of the flip chip integrated circuit die; and
mounting an upper package on the base package substrate including positioning an upper package substrate adjacent to the flip chip protective layer.

2. The method as claimed in claim 1 further comprising applying stacked interconnects between the base package substrate and the upper package substrate.

3. The method as claimed in claim 1 further comprising coupling a first integrated circuit die in the upper package to a system interconnect on the base package, the flip chip integrated circuit die, or a combination thereof.

4. The method as claimed in claim 1 further comprising applying an under fill material between the flip chip integrated circuit die and the base package substrate.

5. The method as claimed in claim 1 further comprising providing an inner layer via in the base package substrate.

6. A method of manufacture of an integrated circuit packaging system comprising:
providing a base package substrate having a system side and a base package component side;
mounting a flip chip integrated circuit die on the base package substrate including coupling a chip interconnect between the flip chip integrated circuit die and the base package component side;
applying a flip chip protective layer on the flip chip integrated circuit die including covering only a back side of the flip chip integrated circuit die in which applying the flip chip protective layer includes applying a film, spray, liquid, or a combination thereof; and
mounting an upper package on the base package substrate including positioning a bottom side of an upper package substrate adjacent to the flip chip protective layer.

7. The method as claimed in claim 6 further comprising applying stacked interconnects between the base package substrate and the upper package substrate including applying solder columns, stud bumps, or solder balls.

8. The method as claimed in claim 6 further comprising coupling a first integrated circuit die in the upper package to a system interconnect on the base package, the flip chip integrated circuit die, or a combination thereof.

9. The method as claimed in claim 6 further comprising applying an under fill material between the flip chip integrated circuit die and the base package substrate including the under fill material not contacting the flip chip protective layer.

10. The method as claimed in claim 6 further comprising providing an inner layer via in the base package substrate including coupling a bonding pad on the base package component side to a system contact pad on the system side.

11. An integrated circuit packaging system comprising:
a base package substrate;
a flip chip integrated circuit die on the base package substrate;
a flip chip protective layer on the flip chip integrated circuit die including covering only a back side of the flip chip integrated circuit die; and
an upper package on the base package substrate including an upper package substrate adjacent to the flip chip protective layer.

12. The system as claimed in claim 11 further comprising stacked interconnects positioned between the base package substrate and the upper package substrate.

13. The system as claimed in claim 11 further comprising a first integrated circuit die in the upper package coupled to a system interconnect on the base package, the flip chip integrated circuit die, or a combination thereof.

14. The system as claimed in claim 11 further comprising an under fill material between the flip chip integrated circuit die and the base package substrate.

15. The system as claimed in claim 11 further comprising an inner layer via in the base package substrate.

16. The system as claimed in claim 11 further comprising:
a system side and a base package component side on the base package substrate;
a chip interconnect between the flip chip integrated circuit die and the base package component side; and
a film, spray, liquid, or a combination thereof form the flip chip protective layer.

17. The system as claimed in claim 16 further comprising stacked interconnects between the base package substrate and the upper package substrate includes solder columns, stud bumps, or solder balls.

18. The system as claimed in claim 16 further comprising a first integrated circuit die in the upper package coupled to a system interconnect on the base package, the flip chip integrated circuit die, or a combination thereof.

19. The system as claimed in claim 16 further comprising an under fill material between the flip chip integrated circuit die and the base package substrate includes the under fill material spaced away from the flip chip protective layer.

20. The system as claimed in claim 16 further comprising providing an inner layer via in the base package substrate including a bonding pad on the base package component side coupled to a system contact pad on the system side.
